(19) United States
(12) Patent Application Publication
(10) Pub. No.: US 2025/0130264 A1
(43) Pub. Date: Apr. 24, 2025

(54) ELECTRIC VEHICLE MAINTENANCE DEVICE

(71) Applicant: Midtronics, Inc., Willowbrook, IL (US)

(72) Inventor: Kevin I. Bertness, Batavia, IL (US)

(21) Appl. No.: 18/914,573

(22) Filed: Oct. 14, 2024

Related U.S. Application Data
(60) Provisional application No. 63/591,170, filed on Oct. 18, 2023.

(51) Int. Cl. G01R 31/00; G01R 31/52

(52) U.S. Cl. CPC G01R 31/007; G01R 31/52

(57) ABSTRACT

A maintenance device couples to electrical circuitry of an electric vehicle and performs maintenance on the vehicle. Electrical connectors couple to electrical circuitry of the vehicle. Measurement circuity couples to the electrical connectors. A controller couples to the measurement circuitry and collects information from the measurement circuitry and responsively makes a diagnostic determination. An apparatus for safety testing of electrical components in an electric vehicle includes a low voltage data connector which couples to a data port of the electric vehicle. A test connector couples a test signal to an electrical component of the vehicle and a test signal source having a signal generator couples to a voltage divider. The voltage divider generates the test signal and a monitor signal, Measurement circuitry couples to the monitor signal and to the low voltage data connector. The measurement circuitry identifies a current leakage based upon the monitor signal.

### CROSS-REFERENCE TO RELATED APPLICATION

The present application is based on and claims the benefit of U.S. provisional patent application Ser. No. 63/591,170, filed Oct. 18, 2023, the contents of which are hereby incorporated by reference in their entirety

### BACKGROUND

The present invention relates to electric vehicles of the type which use battery packs for storing electricity which is used to power the vehicle. This includes both hybrid and purely electric vehicles. More specifically, the present invention relates to the maintenance and diagnostics of electrical components and systems such battery packs along used in electric vehicles.

Traditionally, automotive vehicles have used internal combustion engines as their power source. However, vehicles which are electrically powered are finding widespread use. Such vehicle can provide increased fuel efficiency and can be operated using alternative energy sources.

Some types of electric vehicles are completely powered using electric motors and electricity. Other types of electric vehicles include an internal combustion engine. The internal combustion engine can be used to generate electricity and supplement the power delivered by the electric motor. These types of vehicles are known as “hybrid” electric vehicles.

Operation of an electric vehicle requires a power source capable of providing large amounts of electricity. Typically, electric vehicles store electricity in large battery packs which consist of a plurality of batteries. These batteries may be formed by a number of individual cells, or may themselves be individual cells, depending on the configuration of the battery and battery pack. The packs are large, replacement can be expensive, and they can be difficult to access and maintain. Further, it is desirable to test the safety of the vehicle and its components.

Various techniques have been pioneered by Dr. Keith S. Champlin and Midtronics, Inc. of Willowbrook, Ill. for testing storage batteries, electric and hybrid vehicles and vehicle electrical systems using a number of techniques including measuring a dynamic parameter of the battery such as the dynamic conductance of the battery, as well as other techniques. These techniques are described in a number of United States patents, for example, U.S. Pat. No. 3,873,911, issued Mar. 25, 1975, to Champlin; U.S. Pat. No. 3,909,708, issued Sep. 30, 1975, to Champlin; U.S. Pat. No. 4,816,768, issued Mar. 28, 1989, to Champlin; U.S. Pat. No. 4,825,170, issued Apr. 25, 1989, to Champlin; U.S. Pat. No. 4,881,038, issued Nov. 14, 1989, to Champlin; U.S. Pat. No. 4,912,416, issued Mar. 27, 1990, to Champlin; U.S. Pat. No. 5,140,269, issued Aug. 18, 1992, to Champlin; U.S. Pat. No. 5,343,380, issued Aug. 30, 1994; U.S. Pat. No. 5,572,136, issued Nov. 5, 1996; U.S. Pat. No. 5,574,355, issued Nov. 12, 1996; U.S. Pat. No. 5,583,416, issued Dec. 10, 1996; U.S. Pat. No. 5,585,728, issued Dec. 17, 1996; U.S. Pat. No. 5,589,757, issued Dec. 31, 1996; U.S. Pat. No. 5,592,093, issued Jan. 7, 1997; U.S. Pat. No. 5,598,098, issued Jan. 28, 1997; U.S. Pat. No. 5,656,920, issued Aug. 12, 1997; U.S. Pat. No. 5,757,192, issued May 26, 1998; U.S. Pat. No. 5,821,756, issued Oct. 13, 1998; U.S. Pat. No. 5,831,435, issued Nov. 3, 1998; U.S. Pat. No. 5,871,858, issued Feb. 16, 1999; U.S. Pat. No. 5,914,605, issued Jun. 22, 1999; U.S. Pat. No. 5,945,829, issued Aug. 31, 1999; U.S. Pat. No. 6,002,238, issued Dec. 14, 1999; U.S. Pat. No. 6,037,751, issued Mar. 14, 2000; U.S. Pat. No. 6,037,777, issued Mar. 14, 2000; U.S. Pat. No. 6,051,976, issued Apr. 18, 2000; U.S. Pat. No. 6,081,098, issued Jun. 27, 2000; U.S. Pat. No. 6,091,245, issued Jul. 18, 2000; U.S. Pat. No. 6,104,167, issued Aug. 15, 2000; U.S. Pat. No. 6,137,269, issued Oct. 24, 2000; U.S. Pat. No. 6,163,156, issued Dec. 19, 2000; U.S. Pat. No. 6,172,483, issued Jan. 9, 2001; U.S. Pat. No. 6,172,505, issued Jan. 9, 2001; U.S. Pat. No. 6,222,369, issued Apr. 24, 2001; U.S. Pat. No. 6,225,808, issued May 1, 2001; U.S. Pat. No. 6,249,124, issued Jun. 19, 2001; U.S. Pat. No. 6,259,254, issued Jul. 10, 2001; U.S. Pat. No. 6,262,563, issued Jul. 17, 2001; U.S. Pat. No. 6,294,896, issued Sep. 25, 2001; U.S. Pat. No. 6,294,897, issued Sep. 25, 2001; U.S. Pat. No. 6,304,087, issued Oct. 16, 2001; U.S. Pat. No. 6,310,481, issued Oct. 30, 2001; U.S. Pat. No. 6,313,607, issued Nov. 6, 2001; U.S. Pat. No. 6,313,608, issued Nov. 6, 2001; U.S. Pat. No. 6,316,914, issued Nov. 13, 2001; U.S. Pat. No. 6,323,650, issued Nov. 27, 2001; U.S. Pat. No. 6,329,793, issued Dec. 11, 2001; U.S. Pat. No. 6,331,762, issued Dec. 18, 2001; U.S. Pat. No. 6,332,113, issued Dec. 18, 2001; U.S. Pat. No. 6,351,102, issued Feb. 26, 2002; U.S. Pat. No. 6,359,441, issued Mar. 19, 2002; U.S. Pat. No. 6,363,303, issued Mar. 26, 2002; U.S. Pat. No. 6,377,031, issued Apr. 23, 2002; U.S. Pat. No. 6,392,414, issued May 21, 2002; U.S. Pat. No. 6,417,669, issued Jul. 9, 2002; U.S. Pat. No. 6,424,158, issued Jul. 23, 2002; U.S. Pat. No. 6,441,585, issued Aug. 17, 2002; U.S. Pat. No. 6,437,957, issued Aug. 20, 2002; U.S. Pat. No. 6,445,158, issued Sep. 3, 2002; U.S. Pat. No. 6,456,045; U.S. Pat. No. 6,466,025, issued Oct. 15, 2002; U.S. Pat. No. 6,465,908, issued Oct. 15, 2002; U.S. Pat. No. 6,466,026, issued Oct. 15, 2002; U.S. Pat. No. 6,469,511, issued Nov. 22, 2002; U.S. Pat. No. 6,495,990, issued Dec. 17, 2002; U.S. Pat. No. 6,497,209, issued Dec. 24, 2002; U.S. Pat. No. 6,507,196, issued Jan. 14, 2003; U.S. Pat. No. 6,534,993; issued Mar. 18, 2003; U.S. Pat. No. 6,544,078, issued Apr. 8, 2003; U.S. Pat. No. 6,556,019, issued Apr. 29, 2003; U.S. Pat. No. 6,566,883, issued May 20, 2003; U.S. Pat. No. 6,586,941, issued Jul. 1, 2003; U.S. Pat. No. 6,597,150, issued Jul. 22, 2003; U.S. Pat. No. 6,621,272, issued Sep. 16, 2003; U.S. Pat. No. 6,623,314, issued Sep. 23, 2003; U.S. Pat. No. 6,633,165, issued Oct. 14, 2003; U.S. Pat. No. 6,635,974, issued Oct. 21, 2003; U.S. Pat. No. 6,696,819, issued February 24, 20144; U.S. Pat. No. 6,707,303, issued Mar. 16, 2004; U.S. Pat. No. 6,737,831, issued May 18, 2004; U.S. Pat. No. 6,744,149, issued Jun. 1, 2004; U.S. Pat. No. 6,759,849, issued Jul. 6, 2004; U.S. Pat. No. 6,781,382, issued Aug. 24, 2004; U.S. Pat. No. 6,788,025, filed Sep. 7, 2004; U.S. Pat. No. 6,795,782, issued Sep. 21, 2004; U.S. Pat. No. 6,805,090, filed Oct. 19, 2004; U.S. Pat. No. 6,806,716, filed Oct. 19, 2004; U.S. Pat. No. 6,850,037, filed Feb. 1, 2005; U.S. Pat. No. 6,850,037, issued Feb. 1, 2005; U.S. Pat. No. 6,871,151, issued Mar. 22, 2005; U.S. Pat. No. 6,885,195, issued Apr. 26, 2005; U.S. Pat. No. 6,888,468, issued May 3, 2005; U.S. Pat. No. 6,891,378, issued May 10, 2005; U.S. Pat. No. 6,906,522, issued Jun. 14, 2005; U.S. Pat. No. 6,906,523, issued Jun. 14, 2005; U.S. Pat. No. 6,909,287, issued Jun. 21, 2005; U.S. Pat. No. 6,914,413, issued Jul. 5, 2005; U.S. Pat. No. 6,913,483, issued Jul. 5, 2005; U.S. Pat. No. 6,930,485, issued Aug. 16, 2005; U.S. Pat. No. 6,933,727, issued August 23, 200; U.S. Pat. No. 6,941,234, filed Sep. 6, 2005; U.S. Pat. No. 6,967,484, issued Nov. 22, 2005; U.S. Pat. No. 6,998,847, issued Feb. 14, 2006; U.S. Pat. No. 7,003,410, issued Feb. 21, 2006; U.S. Pat. No. 7,003,411, issued Feb. 21, 2006; U.S. Pat. No. 7,012,433, issued Mar. 14, 2006; U.S. Pat. No. 7,015,674, issued Mar. 21, 2006; U.S. Pat. No. 7,034,541, issued Apr. 25, 2006; U.S. Pat. No. 7,039,533, issued May 2, 2006; U.S. Pat. No. 7,058,525, issued Jun. 6, 2006; U.S. Pat. No. 7,081,755, issued Jul. 25, 2006; U.S. Pat. No. 7,106,070, issued Sep. 12, 2006; U.S. Pat. No. 7,116,109, issued Oct. 3, 2006; U.S. Pat. No. 7,119,686, issued Oct. 10, 2006; and U.S. Pat. No. 7,126,341, issued Oct. 24, 2006; U.S. Pat. No. 7,154,276, issued Dec. 26, 2006; U.S. Pat. No. 7,198,510, issued Apr. 3, 2007; U.S. Pat. No. 7,363,175, issued Apr. 22, 2008; U.S. Pat. No. 7,208,914, issued Apr. 24, 2007; U.S. Pat. No. 7,246,015, issued Jul. 17, 2007; U.S. Pat. No. 7,295,936, issued Nov. 13, 2007; U.S. Pat. No. 7,319,304, issued Jan. 15, 2008; U.S. Pat. No. 7,363,175, issued Apr. 22, 2008; U.S. Pat. No. 7,398,176, issued Jul. 8, 2008; U.S. Pat. No. 7,408,358, issued Aug. 5, 2008; U.S. Pat. No. 7,425,833, issued Sep. 16, 2008; U.S. Pat. No. 7,446,536, issued Nov. 4, 2008; U.S. Pat. No. 7,479,763, issued Jan. 20, 2009; U.S. Pat. No. 7,498,767, issued Mar. 3, 2009; U.S. Pat. No. 7,501,795, issued Mar. 10, 2009; U.S. Pat. No. 7,505,856, issued Mar. 17, 2009; U.S. Pat. No. 7,545,146, issued Jun. 9, 2009; U.S. Pat. No. 7,557,586, issued Jul. 7, 2009; U.S. Pat. No. 7,595,643, issued Sep. 29, 2009; U.S. Pat. No. 7,598,699, issued Oct. 6, 2009; U.S. Pat. No. 7,598,744, issued Oct. 6, 2009; U.S. Pat. No. 7,598,743, issued Oct. 6, 2009; U.S. Pat. No. 7,619,417, issued Nov. 17, 2009; U.S. Pat. No. 7,642,786, issued Jan. 5, 2010; U.S. Pat. No. 7,642,787, issued Jan. 5, 2010; U.S. Pat. No. 7,656,162, issued Feb. 2, 2010; U.S. Pat. No. 7,688,074, issued Mar. 30, 2010; U.S. Pat. No. 7,705,602, issued Apr. 27, 2010; U.S. Pat. No. 7,706,992, issued Apr. 27, 2010; U.S. Pat. No. 7,710,119, issued May 4, 2010; U.S. Pat. No. 7,723,993, issued May 25, 2010; U.S. Pat. No. 7,728,597, issued Jun. 1, 2010; U.S. Pat. No. 7,772,850, issued Aug. 10, 2010; U.S. Pat. No. 7,774,151, issued Aug. 10, 2010; U.S. Pat. No. 7,777,612, issued Aug. 17, 2010; U.S. Pat. No. 7,791,348, issued Sep. 7, 2010; U.S. Pat. No. 7,808,375, issued Oct. 5, 2010; U.S. Pat. No. 7,924,015, issued Apr. 12, 2011; U.S. Pat. No. 7,940,053, issued May 10, 2011; U.S. Pat. No. 7,940,052, issued May 10, 2011; U.S. Pat. No. 7,959,476, issued Jun. 14, 2011; U.S. Pat. No. 7,977,914, issued Jul. 12, 2011; U.S. Pat. No. 7,999,505, issued Aug. 16, 2011; U.S. Patent No. D643,759, issued Aug. 23, 2011; U.S. Pat. No. 8,164,343, issued Apr. 24, 2012; U.S. Pat. No. 8,198,900, issued Jun. 12, 2012; U.S. Pat. No. 8,203,345, issued Jun. 19, 2012; U.S. Pat. No. 8,237,448, issued Aug. 7, 2012; U.S. Pat. No. 8,306,690, issued Nov. 6, 2012; U.S. Pat. No. 8,344,685, issued Jan. 1, 2013; U.S. Pat. No. 8,436,619, issued May 7, 2013; U.S. Pat. No. 8,442,877, issued May 14, 2013; U.S. Pat. No. 8,493,022, issued Jul. 23, 2013; U.S. Patent No. D687,727, issued Aug. 13, 2013; U.S. Pat. No. 8,513,949, issued Aug. 20, 2013; U.S. Pat. No. 8,674,654, issued Mar. 18, 2014; U.S. Pat. No. 8,674,711, issued Mar. 18, 2014; U.S. Pat. No. 8,704,483, issued Apr. 22, 2014; U.S. Pat. No. 8,738,309, issued May 27, 2014; U.S. Pat. No. 8,754,653, issued Jun. 17, 2014; U.S. U.S. Pat. No. 8,872,516, issued Oct. 28, 2014; U.S. Pat. No. 8,872,517, issued Oct. 28, 2014; U.S. Pat. No. 8,958,998, issued Feb. 17, 2015; U.S. Pat. No. 8,963,550, issued Feb. 24, 2015; U.S. Pat. No. 9,018,958, issued Apr. 28, 2015; U.S. Pat. No. 9,052,366, issued Jun. 9, 2015; U.S. Pat. No. 9,201,120, issued Dec. 1, 2015; U.S. Pat. No. 9,229,062, issued January 5, 20126; U.S. Pat. No. 9,244,100, issued Jan. 26, 2016; U.S. Pat. No. 9,255,955, issued Feb. 9, 2016; U.S. Pat. No. 9,274,157, issued Mar. 1, 2016; U.S. Pat. No. 9,312,575, issued Apr. 12, 2016; U.S. Pat. No. 9,335,362, issued May 10, 2016; U.S. Pat. No. 9,425,487, issued Aug. 23, 2016; U.S. Pat. No. 9,419,311, issued Aug. 16, 2016; U.S. Pat. No. 9,496,720, issued Nov. 15, 2016; U.S. Pat. No. 9,588,185, issued Mar. 7, 2017; U.S. Pat. No. 9,923,289, issued Mar. 20, 2018; U.S. Pat. No. 9,966,676, issued May 8, 2018; U.S. Pat. No. 10,046,649, issued Aug. 14, 2018; U.S. Pat. No. 10,222,397, issued Mar. 5, 2019; U.S. Pat. No. 10,317,468, issued Jun. 11, 2019; U.S. Pat. No. 10,429,449, issued Oct. 1, 2019; U.S. Pat. No. 10,473,555, issued Nov. 12, 2019; U.S. Pat. No. 10,608,353, issued Mar. 31, 2020; U.S. Pat. No. 10,843,574, issued Nov. 24, 2020; U.S. Pat. No. 11,054,480, issued Jul. 6, 2021; U.S. Pat. No. 11,325,479, issued May 10, 2022; U.S. Pat. No. 11,474,153, issued Oct. 18, 2022; U.S. Pat. No. 11,486,930, issued Nov. 1, 2022; U.S. Pat. No. 11,513,160, issued Nov. 29, 2022; U.S. Pat. No. 11,545,839, issued Jan. 3, 2023; U.S. Pat. No. 11,548,404, issued Jan. 10, 2023; U.S. Pat. No. 11,566,972, issued Jan. 31, 2023; U.S. Pat. No. 11,650,259, issued May 16, 2023; U.S. Pat. No. 11,668,779, issued Jun. 6, 2023; U.S. Pat. No. 11,740,294, issued Aug. 29, 2023; U.S. Pat. No. 11,926,224, issued Mar. 12, 2024; U.S. Pat. No. 11,973,202, issued Apr. 30, 2024; U.S. Ser. No. 09/780,146, filed Feb. 9, 2001, entitled STORAGE BATTERY WITH INTEGRAL BATTERY TESTER; U.S. Ser. No. 09/756,638, filed Jan. 8, 2001, entitled METHOD AND APPARATUS FOR DETERMINING BATTERY PROPERTIES FROM COMPLEX IMPEDANCE/ADMITTANCE; U.S. Ser. No. 09/862,783, filed May 21, 2001, entitled METHOD AND APPARATUS FOR TESTING CELLS AND BATTERIES EMBEDDED IN SERIES/PARALLEL SYSTEMS; U.S. Ser. No. 09/880,473, filed Jun. 13, 2001; entitled BATTERY TEST MODULE; U.S. Ser. No. 10/109,734, filed Mar. 28, 2002, entitled APPARATUS AND METHOD FOR COUNTERACTING SELF DISCHARGE IN A STORAGE BATTERY; U.S. Ser. No. 10/263,473, filed Oct. 2, 2002, entitled ELECTRONIC BATTERY TESTER WITH RELATIVE TEST OUTPUT; U.S. Ser. No. 09/653,963, filed Sep. 1, 2000, entitled SYSTEM AND METHOD FOR CONTROLLING POWER GENERATION AND STORAGE; U.S. Ser. No. 10/174,110, filed Jun. 18, 2002, entitled DAYTIME RUNNING LIGHT CONTROL USING AN INTELLIGENT POWER MANAGEMENT SYSTEM; U.S. Ser. No. 10/258,441, filed Apr. 9, 2003, entitled CURRENT MEASURING CIRCUIT SUITED FOR BATTERIES; U.S. Ser. No. 10/681,666, filed Oct. 8, 2003, entitled ELECTRONIC BATTERY TESTER WITH PROBE LIGHT; U.S. Ser. No. 11/207,419, filed Aug. 19, 2005, entitled SYSTEM FOR AUTOMATICALLY GATHERING BATTERY INFORMATION FOR USE DURING BATTERY TESTER/CHARGING, U.S. Ser. No. 11/356,443, filed Feb. 16, 2006, entitled ELECTRONIC BATTERY TESTER WITH NETWORK COMMUNICATION; U.S. Ser. No. 12/697,485, filed Feb. 1, 2010, entitled ELECTRONIC BATTERY TESTER; U.S. Ser. No. 12/769,911, filed Apr. 29, 2010, entitled STATIONARY BATTERY TESTER; U.S. Ser. No. 13/152,711, filed Jun. 3, 2011, entitled BATTERY PACK MAINTENANCE FOR ELECTRIC VEHICLE; U.S. Ser. No. 14/039,746, filed Sep. 27, 2013, entitled BATTERY PACK MAINTENANCE FOR ELECTRIC VEHICLE; U.S. Ser. No. 14/565,589, filed Dec. 10, 2014, entitled BATTERY TESTER AND BATTERY REGISTRATION TOOL; U.S. Ser. No. 15/017,887, filed Feb. 8, 2016, entitled METHOD AND APPARATUS FOR MEASURING A PARAMETER OF A VEHICLE ELECTRICAL SYSTEM; U.S. Ser. No. 15/049,483, filed Feb. 22, 2016, entitled BATTERY TESTER FOR ELECTRIC VEHICLE; U.S. Ser. No. 15/077,975, filed Mar. 23, 2016, entitled BATTERY MAINTENANCE SYSTEM; U.S. Ser. No. 15/149,579, filed May 9, 2016, entitled BATTERY TESTER FOR ELECTRIC VEHICLE; U.S. Ser. No. 16/253,526, filed Jan. 22, 2019, entitled HIGH CAPACITY BATTERY BALANCER; U.S. Ser. No. 17/364,953, filed Jul. 1, 2021, entitled ELECTRICAL LOAD FOR ELECTRONIC BATTERY TESTER AND ELECTRONIC BATTERY TESTER INCLUDING SUCH ELECTRICAL LOAD; U.S. Ser. No. 17/504,897, filed Oct. 19, 2021, entitled HIGH CAPACITY BATTERY BALANCER; U.S. Ser. No. 17/750,719, filed May 23, 2022, entitled BATTERY MONITORING SYSTEM; U.S. Ser. No. 17/893,412, filed Aug. 23, 2022, entitled POWER ADAPTER FOR AUTOMOTIVE VEHICLE MAINTENANCE DEVICE; U.S. Ser. No. 18/166,702, filed Feb. 9, 2023, entitled BATTERY MAINTENANCE DEVICE WITH HIGH VOLTAGE CONNECTOR; U.S. Ser. No. 18/314,266, filed May 9, 2023, entitled ELECTRONIC BATTERY TESTER, U.S. Ser. No. 18/324,382, filed May 26, 2023, entitled STACKABLE BATTERY MAINTENANCE SYSTEM, U.S. Ser. No. 18/328,827, filed Jun. 5, 2023, entitled ELECTRIC VEHICLE BATTERY STORAGE VESSEL; U.S. Ser. No. 18/337,203, filed Jun. 19, 2023, entitled HIGH USE BATTERY PACK MAINTENANCE; U.S. Ser. No. 18/609,344, filed Mar. 19, 2024, entitled INTELLIGENT MODULE INTERFACE FOR BATTERY MAINTENANCE DEVICE; U.S. Ser. No. 18/616,458, filed Mar. 26, 2024, entitled EV BATTERY CHARGING SOLUTION FOR CONTAINERS; U.S. Ser. No. 18/740,030, filed Jun. 11, 2024; all of which are incorporated herein by reference in their entireties.

### SUMMARY

The present invention includes a battery pack maintenance device for performing maintenance on battery packs of hybrid and/or electrical vehicles (referred herein generally as electric vehicles). Input/output circuitry can be provided for communicating with circuitry of in the battery pack and/or circuitry of the vehicle.

A maintenance device is provided for coupling to electrical circuitry of an electric vehicle and performing maintenance on the battery includes electrical connectors to configured to couple to the electrical circuitry of the vehicle. Measurement circuity couples to the electrical connectors. A controller couples to the measurement circuitry and is configured to collect related information from the measurement circuitry and responsively make a diagnostic determination.

An apparatus for safety testing of electrical components in an electric vehicle includes a low voltage data connector configured to couple to a data port of the electric vehicle. A test connector is configured to couple a test signal to an electrical component of the electric vehicle and a test signal source having a signal generator couples to a voltage divider. The voltage divider generates the test signal and a monitor signal, Measurement circuitry couples to the monitor signal and to the low voltage data connector. The measurement circuitry identifies a current leakage based upon the monitor signal.

In one aspect, an apparatus for safety testing of electrical components in an electric vehicle is provided which includes an optional low voltage data connector configured to couple to a data port of the electric vehicle. A test connector is configured to couple a test signal to an electrical component of the electric vehicle. A test signal source having a signal generator is coupled to a voltage divider. The voltage divider generates the test signal and a monitor signal. Measurement circuitry is coupled to the monitor signal, and a controller is coupled to the measurement circuitry. The controller detects a current leakage based upon the monitor signal.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. The claimed subject matter is not limited to implementations that solve any or all disadvantages noted in the Background.

### BRIEF DESCRIPTION OF THE DRAWINGS

FIG. 1 is a simplified block diagram of a battery maintenance device in accordance with the present invention coupled to an electric vehicle.

FIG. 2 is a more detailed block diagram of the battery maintenance device of FIG. 1.

FIG. 3 is a simplified schematic diagram of the battery maintenance device for use in determining failure or degradation of insulation or other components within the vehicle using a small AC signal source.

FIG. 4 is a simplified block diagram of the maintenance device for probing electrical resistance between two test points, for example between a PE connection in a charging port of a vehicle and an electrical ground location within the vehicle.

### DETAILED DESCRIPTION OF ILLUSTRATIVE EMBODIMENTS

Embodiments of the present disclosure are described more fully hereinafter with reference to the accompanying drawings. Elements that are identified using the same or similar reference characters refer to the same or similar elements. Some elements may not be shown in each of the figures in order to simplify the illustrations.

The various embodiments of the present disclosure may be embodied in many different forms and should not be construed as limited to the specific embodiments set forth herein. Rather, these embodiments are provided so that this disclosure will be thorough and complete, and will fully convey the scope of the present disclosure to those skilled in the art.

Maintenance of automotive vehicles with internal combustion engines is a well-known art. Procedures are known for servicing the internal combustion engine of the vehicles, the drive train, the battery (which is generally used to start the vehicle and operate the electrical devices within the vehicle), and the fuel storage and distribution system. In contrast, widespread use of electrical vehicles is a relatively new phenomenon and there is an ongoing need for improved procedures for performing maintenance on the batteries of such vehicles.

The device of the present invention can be used to test the electrical system of an electric vehicle or provide other maintenance and diagnostics on the battery pack of such a vehicle. In general, this activity can be problematic for a number of reasons. First, different types of electric vehicles use different types of electrical systems and battery packs. The configuration, voltages, and connection to such electrical systems and packs vary greatly. Further, the vehicle itself typically includes “intelligence” to control the charging and discharging, as well as monitoring the status of the battery pack. Further still, some battery packs themselves include “intelligence” to control the charging and discharging of the battery pack, as well as monitor the status of the battery pack. The device of the present invention is capable of interfacing with a databus of the vehicle and/or a databus of the battery pack in order to control and monitor operation of the battery pack and electrical system. The battery pack and/or electrical system may be physically difficult to access, and it may be difficult to obtain electrical connections to the electrical system or battery pack. Additionally, in one aspect, the device also includes a charger function for use in charging some or all of the cells of a battery pack in order to place the battery pack into service.

Electric vehicles typically include “contactors” which are electrically operated relays (switches) used to selectively couple the high voltage from the battery pack to the charging port of the vehicle or to the powerful electric motors used in the drive train of the vehicle. In order to access the battery pack from a location on the vehicle, it is necessary for these contactors to be closed to complete the electrical circuit. However, the controlling electronics of the vehicle and/or battery pack will typically disconnect (open) the contactors when the electric motors or charging port are not in use for safety purposes in order to isolate the battery pack from the vehicle. Thus, in one embodiment, the present invention communicates with the controller of the electrical vehicle or battery pack, or directly with the contactors, to cause the contactors to close and thereby provide access to the high voltage of the battery pack. When communicating with the control system of the vehicle, the device of the present invention can provide information to the vehicle system indicating that it is appropriate for the contactors to close. Thus, failure indications or other errors, including errors associated with a vehicle being in an accident, must be suppressed. Instead, information is provided to the vehicle system by the battery pack maintenance device which indicates that it is appropriate for the contactors to be closed.

Further, in many instances, it is important to determine the safety of electric vehicles in-service. In some regions, for example, traditional vehicles with internal combustion engines undergo a mandatory yearly safety inspection. This may involve checking the brakes, the suspension, exterior lighting, etc. This is similar to an emission check, but is safety related. Further, in some regions, a vehicle cannot be sold without obtaining a certificate of safety.

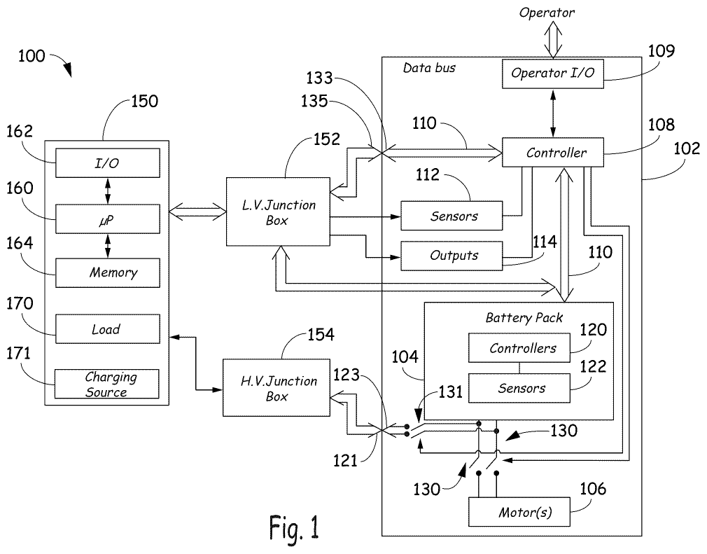

FIG. 1 is a simplified block diagram showing maintenance/diagnostic device 100 coupled to an electric vehicle 102. The vehicle 102 is illustrated in a simple block diagram and includes a battery pack 104 used to power the vehicle 102 including providing power to motor(s) 106 of the vehicle. The vehicle 102 includes a vehicle controller 108 coupled to a databus 110 of the vehicle. The controller 108 receives information regarding operation of the vehicle through sensors 112 and controls operation of the vehicle through outputs 114. Further, the battery pack 104 is illustrated as including its own optional controller 120 which monitors operation of the battery pack 104 using battery pack sensors 122.

During operation, the electric vehicle 102 is controlled by the controller 108, for example, based upon input from a driver through operator I/O 109. Operator I/O 109 can comprise, for example, a foot accelerator input, a brake input, an input indicating a position of a steering wheel, information related to a desired gearing ratio for a drive train, outputs related to operation of the vehicle such as speed, charging information, amount of energy which remains in the battery pack 104, diagnostic information, etc. The controller 108 can control operation of the electric motors 106 to propel the vehicle, as well as monitor and control other systems of the vehicle 102. The controller 120 of battery pack 104 can be used to monitor the operation of the battery pack 104. For example, the sensors 122 may include temperature sensors configured to disconnect the batteries of the battery pack if a threshold temperature is exceeded. Other example sensors include current or voltage sensors, which can be used to monitor charge of the battery pack 104. FIG. 1 also illustrates contactor relays 130 of the vehicle 102 which are used to selectively decouple the battery pack 104 from systems of the vehicle 102 as discussed above. For example, the controller 108 can provide a signal to cause the contactors 130 to close, thereby connecting the battery pack 104 to electrical systems of the vehicle 102.

Device 100 includes a main unit 150 which couples to the vehicle through a low voltage junction box 152 and a high voltage junction box 154. These junction boxes 152, 154 are optional and other techniques may be used for coupling the maintenance device 100 to the vehicle 102. Maintenance device 100 includes a microprocessor 160, I/O circuitry 162 and memory 164 which contains, for example, programming instructions for use by microprocessor 160. The I/O circuitry 162 can be used to both user input, output, remote input, output as well as input and output with vehicle 102. The maintenance device 100 includes a controllable load 170 for use in discharging the battery pack 104. An optional charging source 171 is also provided and can be used in situations in which it is desirable to charge the battery pack 104, for example, to perform maintenance on the battery pack 104. The high voltage junction box 154 is used to provide an electrical connection between terminals of the battery pack 104 and the maintenance device main unit 150. Using this connection, batteries within the battery pack 104 can be discharged using the load 170 or charged using the charging source 171. Similarly, low voltage junction box 152 is used by battery pack maintenance device 100 to couple to low voltage systems of the electric vehicle 102. Such systems include the databus 110 of the vehicle, sensors 112, outputs 114, etc. Through this connection, as discussed above, the maintenance device 100 can gather information regarding the condition of systems within the vehicle 102 including the battery pack 104, and can control operation of systems within the vehicle 102. Similarly, through this connection, the outputs from sensors 112 can be changed or altered whereby altered sensor outputs can be provided to controller 108. This can be used, for example, to cause controller 108 to receive information indicating that the vehicle 102 or battery pack 104 is in a condition which is different than from what the sensors 112 are actually sensing. For example, this connection can be used to cause the contactors 130 to close to thereby provide an electrical connection to the battery pack 104. Further, the low voltage junction box 152 can be used to couple to the controller 120 and/or sensors 122 of the battery pack 104. The junction boxes 152, 154 couple to vehicle 102 through the use of an appropriate connector. The particular connector which is used can be selected based upon the specific type of vehicle 102 and the type of connections which are available to an operator. For example, OBD II connection can be used to couple to the databus 110 of the vehicle. Other plugs or adapters may be used to couple to sensors 112 or outputs 114. A particular style plug may be available for coupling the high voltage junction box 154 to the battery pack 104. If there are no contactors which are available or if they cannot be accessed or are unresponsive, in one configuration clips or other types of clamp on or selectively connectable contactors can be used to perform the coupling.

Vehicle 102 includes a data port 133, such as a OBD II port. This allows device 100 co communication with a databus of the vehicle. In such a configuration, a data connector 135 is provided for connecting to data port 133.

In one configuration, the high voltage connection to the vehicle is made through the vehicle charging port 123 and the device 00 includes a charging plug 121 of the appropriate configuration. The vehicle 102 includes additional contactors 131 which are used to selectively couple the battery pack 104 to the charging port 123. Some charging ports also include a data connection. In such a configuration, data port 133 can be included with charging port 123. Further, some configurations allow the transmission of data over the same wires used to provide the charging connection.

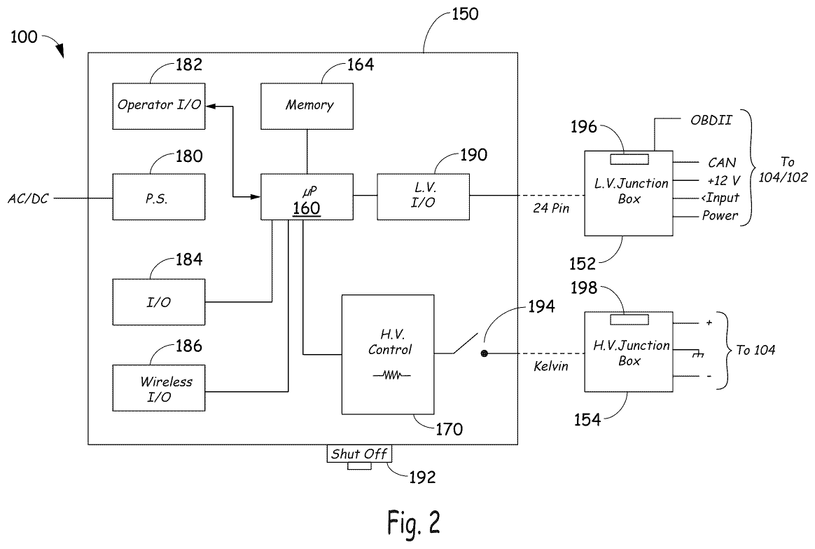

FIG. 2 is a simplified block diagram of a battery pack maintenance device 100 in accordance with one example embodiment of the present invention. The device includes a microprocessor 160 which operates in accordance with instructions stored in a memory 164. A power supply is used to provide power to the device. The power supply 180 can be coupled to an AC power source, such as a wall outlet or other high power source, for use in charging the battery pack 104 of the vehicle 102. Additionally, the power supply 180 can be coupled to a DC power source, such as a 12 Volt battery, if the device 100 is only used for discharging of the vehicle battery pack 104. For example, in addition to the battery pack 104, many electric vehicles also include a standard 12 Volt automotive battery. This 12 Volt automotive battery can be used to power maintenance device 100. The microprocessor communicates with an operator using an operator input/output 182. Other input/output circuitry 184 is provided for use in physically connecting to a data communication link such as an RS232, USB connection, Ethernet, etc. An optional wireless I/O circuit 186 is also provided for use in communicating in accordance with wireless technologies such as Wi-Fi techniques, Bluetooth®, Zigbee®, etc. Low voltage input/output circuitry 190 is provided for use in communicating with the databus of the vehicle 108, the databus of the battery pack 104, or receiving other inputs or providing outputs to the vehicle 102. Examples include the CAN communication protocol, OBDII, etc. Additionally, contact closures or other voltage inputs or outputs can be applied to the vehicle using the low voltage I/O circuitry 190. FIG. 2 also illustrates an operator shut off switch 192 which can be activated to immediately disconnect the high voltage control 170 from the battery 104 using disconnect switch 194. Other circuit configurations can be used to implement this shut off capability. This configuration allows an operator to perform an emergency shut off or otherwise immediately disconnect the device 100 from the battery if desired.

The low voltage junction box 152 also provides an optional power output. This power can be used, for example, to power components of the vehicle 102 if the vehicle 102 has lost power. This can be useful, for example, to provide power to the controller 108 of the vehicle 102 such that information may be gathered from the vehicle and various components of the vehicle can be controlled such as the contactors 130.

In one configuration, the connection between the high voltage control circuitry 170 and the high voltage junction box 154 is through Kelvin type connectors. This can be used to eliminate the voltage drop which occurs when large currents are drawn through wiring to thereby provide more accurate voltage measurements. The actual connection between the junction box 154 and the battery pack 104 need not be through a Kelvin connection if the distance between the junction box 154 and the battery pack 104 is sufficiently short for the voltage drop across the connection leads to be negligible. Isolation circuitry such as fuses may be provided in the junction box 154 to prevent the application of a high voltage or current to the maintenance device 100 and thereby protect circuitry in the device. Similarly, the low voltage junction box 152 and/or the low voltage I/O 190 may include isolation circuitry such as optical isolators, inductors to provide inductive coupling, or other techniques. The low voltage junction box 152 may also include an optional user output and/or input 196. For example, this may be a display which can be observed by an operator. An example display includes an LED display, or individual LEDs, which provides an indication to the operator regarding the functioning of the low voltage junction box, the vehicle, or the battery pack. This can be used to visually inform an operator regarding the various functions being performed by the low voltage junction box, voltages detected by the low voltage junction box. A visual output and/or input 198 can be provided on the high voltage junction box 154.

The appropriate high voltage junction box 154 and low voltage junction box 152 can be selected based upon the particular vehicle 102 or battery pack 104 being inspected. Similarly, the junction boxes 152, 154 can be selected based upon the types of connections which are available in a particular situation. For example, if the vehicle his damaged, it may be impossible to couple to the battery pack 104 through available connectors. Instead, a junction box 154 can be employed which includes connection probes which can be coupled directly to the battery pack 104. Further still, if such a connection is not available or is damaged, connectors can be provided for coupling to individual cells or batteries within the battery pack 104.

The use of the low voltage and high voltage junction boxes 152, 154 are advantageous for a number of reasons. The junction boxes can be used to provide a standardized connection to the circuitry of the maintenance device 100. From a junction box 152, 154, specialized connectors can be provided for use with different types of vehicles and/or battery packs. Similarly, different types of junction boxes 152, 154 can be utilized for different vehicles and/or battery packs. The junction boxes 152, 154 allow a single set of cable connection to extend between the device 100 and a remote location. This provides better cable management, ease of use, and increased accuracy.

In addition to use as a load for discharging the battery, the high voltage control circuitry may also optionally include a charging for use in charging the battery.

When the device 100 is coupled to a vehicle 102 which has been in an accident, the device can perform various tests on the vehicle 102 to determine the condition of the vehicle and the battery. For example, in one aspect, the device 100 detects a leakage between the positive and negative terminals of the battery pack 102 and the ground or chassis of the vehicle 102.

During discharging of the vehicle battery pack 104, data can be collected from the battery pack. For example, battery packs typically include sensors 122 such as voltage, current and temperature sensors arranged to collect data from various locations within the battery pack. This information can be obtained by the maintenance device 100 via the coupling to the databus 110. During discharge, any abnormal parameters measured by the sensors can be used to control the discharge. For example, if the battery pack 104 is experiencing excessive heating, the discharge rate can be reduced until the battery temperature returns to an acceptable level. If any of the internal temperature sensors of the battery pack are not functioning, an external battery pack temperature sensor can be used to detect the temperature of the battery pack. Similarly, if cells within the pack are experiencing an abnormally high current discharge, the discharge rate can be reduced. Further still, if such data cannot be obtained because the sensors are damages or the databus is damaged or inaccessible; the maintenance device 100 can automatically enter a slow/safe discharge state to ensure that the battery is not damaged.

Some electrical vehicles include what is referred to as a “pre-charge contactor.” The pre-charge contactor can be used to charge capacitances of the vehicle at a slow and controlled rate prior to switching in the main contactor 130 shown in FIG. 1. This prevents excessive current discharge from the battery pack when the main contactor is activated and the pack is directly coupled to the loads of the vehicle including the traction module of the vehicle which is used to control electric motors of the vehicle.

In another aspect, some or all of the information obtained during testing is retrieved and stored, for example in the memory 164 shown in FIG. 1, for subsequent access. This information can be offloaded to another device, for example a USB drive or the like, or transmitted over a network connection. The information can be information which is downloaded from the controller 108 of the vehicle 102 and may also be information related to how the vehicle battery pack 104 was discharged and removed of service.

In one configuration, the voltage sensor 232 is used to detect leakage currents in the battery undergoing discharge. The device can also monitor battery cell voltages and temperatures to ensure that unsafe conditions are not being created during discharge.

The input/output circuitry 190 can be used to connect to a databus of the vehicle, for example, through an OBDII connection in order to collect information such as VIN, software and hardware version numbers, etc. The device can communicate with the battery ECU (Electronic Control Unit) using any appropriate protocol including CAN, LIN, or others, in order to obtain specific battery information and discharge protocols. The device can be connected as a slave unit to another piece of shop equipment, either using a hardwired connection or a wireless connection such as Bluetooth or Wi-Fi. Reverse polarity protection as well as overvoltage protection can be provided. Other safety techniques for electrical potential, temperature and axis points can be fully interlocked to prevent operation of the unit. In one configuration, the input/output 184 can include a barcode scanner which can then be used to capture specific information such as battery type or serial number as well as vehicle identification number, etc. In another example configuration, input/output circuitry 184 can include a remote temperature sensor that can be electrically coupled to the discharger to report battery temperature. This is useful when internal battery temperature sensors are damaged or inoperative. The devices are scalable such that multiple controllable loads 100 can be connected in parallel. Relay contacts can also be provided and available externally to control various circuits on the battery pack undergoing discharge. Additional voltage sensing connections such as those provided by junction box 152 can be used to monitor various circuits on the battery pack.

Another example configuration includes a high voltage DC to DC converter such as power supply 180 shown in FIG. 2. In such a configuration, the high voltage output from the battery pack can be converted to a lower DC voltage for use in powering the device.

As discussed above, in some configurations the present invention can be arranged to measure a dynamic parameter of an electrical component of the vehicle. In such a configuration, a forcing function is applied to electrical components and a dynamic parameter such as dynamic conductance, resistance, admittance, etc. can be determined based upon a change in the voltage across the battery pack and the current flowing through the battery pack. The forcing function can be any type of function which has a time varying aspect, including an AC signal or a transient signal.

Different types of junction boxes and connection cables can be used based upon the particular type of vehicle and battery pack under maintenance. The microprocessor can provide information to the operator, prompting the operator to use the appropriate junction box or cable. This can be based upon the operator inputting the vehicle identification number (VIN) to the microprocessor, or other identifying information, including an identification number associated with the battery pack. During discharging of the battery pack, the microprocessor can also provide information to the operator which indicates the time remaining to complete the discharge. The microprocessor 160 can also detect if the correct junction box and cable have been coupled to the device and to the battery pack for the particular battery pack and vehicle under maintenance. Information can be provided to the operator if the wrong cabling or junction box has been employed.

As discussed above, the device 100 can include multiple connectors for use in connecting the low voltage junction box 152 and/or the high voltage junction box 154 to the vehicle 102 and/or battery pack 104. This allows the device 100 to easily be modified to interact with different types of batteries or vehicles by simply selecting the appropriate connector. In one configuration, the connectors include some type of identifier which can be read by the device 100 whereby the microprocessor 160 and device 100 can receive information to thereby identify the type of connector in use. This allows the microprocessor 100 to know what types of information or tests may be available through the various connectors. In another example, the operator uses operator I/O 182 shown in FIG. 2 to input information to the microprocessor 160 related to the type of connector(s) being used. In another example embodiment, the microprocessor 160 may receive information which identifies the type of vehicle or battery on which maintenance is being performed. This information can be input by an operator using the operator I/O 182 or through some other means such as by communicating with the databus of the vehicle, scanning a barcode or other type of input, etc. Based upon this information, the microprocessor can provide an output to the operator using operator I/O 182 which informs the operator which type of interconnect cable should be used to couple the low voltage junction box 152 and/or the high voltage junction box 154 to the vehicle and/or battery pack.

The operator I/O 182 may include a display along with a keypad input or touchscreen. The input may take various formats, for example, a menu driven format in which an operator moves through a series of menus selecting various options and configurations. Similarly, the operator I/O 182 can be used by the microprocessor 160 to step the operator through a maintenance procedure. In one configuration, the memory 164 is configured to receive a user identification which identifies the operator using the equipment. This can be input, for example, through operator I/O 182 and allows information related to the maintenance being performed to be associated with information which identifies a particular operator. Additional information that can be associated with the maintenance data include tests performed on the vehicle and/or battery, logging information, steps performed in accordance with the maintenance, date and time information, geographical location information, environmental information including temperature, test conditions, etc., along with any other desired information. This information can be stored in memory 164 for concurrent or subsequent transmission to another device or location for further analysis. Memory 164 can also store program instructions, battery parameters, vehicle parameters, testing or maintenance information or procedures, as well as other information. These programming instructions can be updated, for example, using I/O 184 or 186, through a USB flash drive, SD card or other memory device, or through some other means as desired. This allows the device 100 to be modified, for example, if new types of vehicles or battery pack configurations are released, if new testing or maintenance procedures are desired, etc.

As discussed herein, the maintenance device 100 can be used for testing safety related aspects of the vehicle 102. The low voltage connection 152 can couple to the databus of the vehicle, such as through an OBD II connection or the low voltage connection of the charging input, and the high voltage connection can couple to various points in the vehicle power train through a connector or a probe, or to the high voltage connection of the vehicle charging input. When testing a vehicle for safety relating aspects, an initial assumption can be made that the vehicle is safe and a series of tests are run to determine if this assumption is incorrect. A series of tests are performed and if any test fails, the vehicle is determined to be unsafe. This is essentially a logical OR function. Any one of the tests which is failed can create questions regarding vehicle safety. The OR function can be divided into two categories: 1) data that the vehicle computer (or ECU, Electronic Control Unit) is aware of and can report, and 2) data that can be independently identified externally by the maintenance device 100. This can also be used to ensure that the safety determination is not biased. The output provides a “state of safety” or “SOS” of the vehicle.

The maintenance device 100 can operate as a scan tool connected to the data port of the vehicle. Any of the following are example parameters that can create questions regarding safety that warrant further investigation:
Absolute battery voltage below a given threshold.
Individual cell voltage below a given threshold.
Standard deviation of cell voltages above a given threshold.
[MAX-MIN] cell voltages above a given threshold.
Cell conductance below a certain value. Note that this may not be directly reported by ECU but can be calculated using virtual conductance techniques such a monitoring current through a cell and voltage across a cell.
Cell conductance standard deviation above a certain threshold.
Faults reported by the ECU.
Any cell not reporting data.
Any temperature sensor not reporting data.
Any current or voltage sensor not reporting.
Airbags were deployed.
Internal current leakage fault.
Other safety related PID (parameter ID) values.

An external validation device, such as maintenance device 100:
Can report any current leakage value of a battery pack to the vehicle chassis resulting from one of the following:
   Insulation breakdown or degradation
   Electrolyte seepage
   Burst cells
   Mechanical breakdown of internal components
   Contamination in battery pack
   Seal failure
   Water ingress
   Structural damage to pack

Although some of these parameters can be measured with a scan tool, with the present invention a determination of safety based on the values, or combination of values is made, for example by microprocessor 160. The parameters can be processed by a rule set to arrive at a safety determination. In order to measure leakage current, device 100 can be coupled to a battery pole, for example the B+, B−MSD, or auxiliary ports of battery pack 104 and determine the impedance to ground at any other point in the circuit. With this measurement, it does not matter where the fault is relative to the test point. An adapter can be provided that is received in the CCS DC charge point, sending commands to close the contactors, and check from one of the poles. Although some battery packs have internal leakage circuits, they may be unreliable and will not suffice for safety inspections.

Another aspect of the invention relates to measuring electrical isolation of components. Isolation is conventionally measured by what is referred to as a HIPOT test, which stands for high potential. This is used to check the integrity of insulation systems, primarily on AC wiring. A voltage is selected that is some considerable factor above the working voltage of the system, and applied to each conductor relative to another component, such as the vehicle chassis. Ideally, there should be no conduction. However, in practice, there is always some form of a high resistance electrical pathway and the actual isolation will be greater than some selected number of megohms. It is considered a non-destructive test, in that the insulation is not damaged as a result of this test. The present invention includes checking the insulation of the AC charge port using either this method, or a small signal AC based forcing function.

For battery systems, regardless of the presence of any leakage path, the leakage is not visible to the test equipment unless the potential applied exceeds the battery string voltage. However, at this voltage level, the test is a destructive test. As such, this test of the safety of the insulation actually results in a degradation to the system. This is because of the sensitive nature of battery cells. They are not simple insulation systems, but complex systems with electrolyte, separators, electrodes, and other components. Exceeding a voltage across a cell causes breakdown of the separator, which leads to failure. This method is used during the manufacture of cells as a spot check of separator integrity, but those cells are discarded following the test procedure. For this scenario, a small signal AC forcing function can be used to detect the leakage without exceeding the battery voltage. The AC signal will pass through the cell, elevating both the anode and cathode simultaneously.

In one aspect, a small AC voltage at a low frequency is generated. The frequency can be chosen as desired, but preferably in the ELF (extremely low frequency) range. In specific configurations, 50 HZ or 100 HZ are used. However, other frequencies may be used as desired. This signal can be applied to a tuned circuit (voltage divider) and capacitively coupled the into the battery string. The output of the voltage divider is monitored between the divider and the coupling capacitor. When the circuit is “loaded” on the battery side due to the presence of isolation resistance, the test equipment monitors the degradation of the drive signal and can solve the resulting equation for the unknown isolation resistance. Further, this configuration is not sensitive to where the leakage is located within the high voltage string. Although a specific configuration is set forth herein, any configuration can be used to generate a test signal and a monitor signal.

The measurement equipment can test the leakage of the available circuits, either through the charge port, or any other point in the system that allows access or an electrical probe or connection. This may be at the manual safety disconnect, which provides access to the individual halves or sections of the battery system. Other locations can be accessed, for example, through any high voltage accessory port, such as the AC compressor.

Vehicles generally have two types of charge ports: Those that accept AC power only (either single or 3 phase), or those that accept both AC and DC.

The measurement system can test all types of connections. The AC connections can be tested by either the AC signal method disclosed herein, or a conventional HIPOT test. The DC charging connection can only be tested using the AC signal model.

Electric vehicle charging connectors vary widely by manufacturer and location. One preferred connection is a standard unit with the NACS (North American Charging System) connector. This type of connector is preferred because it provides AC and DC connections, along with data communication, in a very small format. Adapters can be used that convert this to other connector standard such as J1772, CCS1, CCS2, or others. In another configuration, region specific units can be provided that have the appropriate connector built in. The main assembly is the same, but customized connectors can fit into a storage area in the housing of device 100.

Additionally, the AC or DC charge contactors 131 can be instructed to close, Communication can be achieved with the vehicle using, for example, the data connection when element 121 is configured as a charging plug. For example, the control pilot pin can be used to instruct contactors 131 to close. For example, using the HomePlug Green PHY protocol. Such configurations allow communication of data over a power connection.

There are vehicles which are equipped with vehicle-to-grid charging connection. In such a configuration, the vehicle does not expect to see a charger connected to the charging port and instead receives a line voltage AC input. However, most vehicles do not have this ability, in which case, the vehicle must be instructed to close the contactors without a charger present. One way which this can be implemented with some vehicles is simply to communicate to the vehicle computer indicating that there is a charger connected. Once the contacts close, there is no way for the vehicle to detect this because the vehicle sees the same voltage outside the car and inside the car because the voltages are all generated by the vehicle battery. Another technique that can be used to instruct the contactors to close is to generate a high voltage reference at a low current level (not enough to charge, but enough for the vehicle to read a voltage), Once the contactors close, they will remain closed.

Element 121 can be configured as an electrical connector configured to connect to various standard connectors of vehicle 102 such as connectors used to connect to battery pack 104, an internal DC to DC converter in vehicle 102, the charging port 123, or other components. Element 121 can also be configured as a probe such that an operator can manually touch the probe 121 to various locations in vehicle 102. For example, probe 121 can be used to probe various points along the string of batteries that make up battery pack 104. A display in operator I/O can be used to instruct an operator where to place the probe through written instructions and/or images.

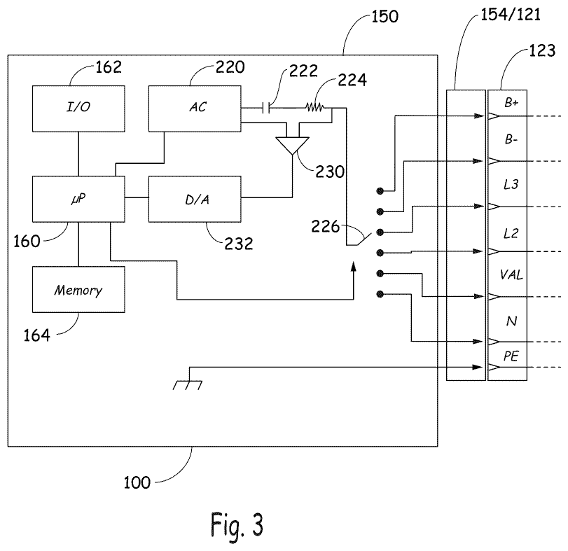

FIG. 3 is a simplified block diagram of device 100 showing circuitry used for testing the resistance between components within the electric vehicle 102 which should be highly electrically insulated, particularly components which are part of the charging and power system of the vehicle 102. Element 123 is illustrated as a charging port and includes a number of charging connections for exemplary purposes. However, any charging technique or standard can be implemented in port 123. Port 123 illustrates DC battery charging connections B+ and B−, along with AC charging connections L1, L2 and L3. The AC charging may be through a single phase or a multiphase AC signal. A neutral connection N is shown along with a ground or earth potential PE. When charging using a DC charge signal applied to the B+ and B−connections, a large amount of charge can be transferred directly into the battery pack 104 at a high voltage and at a high current. AC charging may also be applied to the vehicle 102 using the L1, L2 and L3 connections. However, with AC charging an AC to DC converted within the vehicle 102 must be used to convert the AC charging signal into a DC charging signal suitable for application to battery pack 104. Thus, AC charging typically occurs at a lower charging rate than is possible with DC charging. Further, in FIG. 3, element 121 configured as a charging plug and high voltage junction box 154 are illustrated as a single component. However, this is not a requirement. Preferably, the charging plug can be selectable by an operator such that a specific plug can be selected for connecting to the charging port 123 of a specific type of vehicle.

In the configuration of FIG. 3, device 100 is illustrated as including a controller or microprocessor 160, input/output circuitry 162 and memory 164. A low voltage AC test signal source 220 is provided and controlled by microprocessor 160 and provides an AC test signal to an RC network formed by capacitor 222 and resistor 224 which form a voltage divider. The AC signal generated by source 220 is also referred to herein as a forcing function. The AC signal provided by source 220 may be of any particular form including sine waves, square waves or other wave form shapes and may also include a simple transient signal in some configurations. The AC test signal is coupled to capacitor 222 and resistor 224 which generate a monitor signal applied to one of the input connections of charging port 123 using a controllable switch 226 which operates under the control of microprocessor 160. The switch 262 allows the AC signal to be coupled to any one of the plurality of inputs in the charging port 123. The charging plug 154/121 also connects to the PE connection of the vehicle 102 which couples to an electrical ground of device 100. Measurement circuitry is provided by differential amplifier 230 which is arranged to measure a voltage difference between the AC test signal and the monitor signal apparent on opposing sides of the RC circuit formed by resistor 224 and capacitor 222. The voltage difference is provided to an analog to digital converter 232 which provides a digital signal to microprocessor 160.

In operation, switch 226 is moved to selectively couple the monitor signal generated by the AC test signal to one of the connections in charging port 123. An AC signal from AC source 220 is then applied to the connection through capacitor 222 and resistor 224. If there is any current leakage between the AC input connection and the ground provided by the PE connection, there will be an AC current which flows through resistor 224 and capacitor 222. This will result in a voltage drop across resistor 224 and capacitor 222 which will be sensed by differential amplifier 230. This difference signal is converted into a digital signal for microprocessor 160 using digital to analog converter 232. If the measured resistance is greater than a maximum resistance threshold, microprocessor 160 can provide an indication through I/O circuitry 162 to an operator that there is a potential short circuit or insulation failure in the vehicle 102.

When the charging contactors 131 shown in FIG. 1 are open, the above insulation test will only test the connection through the charging port 123 and to the contactors 131. Additionally, for example, if the AC signal is applied through AC connections L1-3, depending on the configuration of the vehicle, it may also be possible to test the insulation of the AC to DC converter within the vehicle. However, if contactors 121 are closed, the insulation test can be performed through the entire length of the connection from the charging port 123 to the battery pack 104, and into the battery pack 104 as well as to devices to which the battery pack 104 connects. If desired, the system can also perform a HIPOT test using the high voltage circuitry as discussed in connection with FIGS. 1 and 2.

The particular frequency of the AC signal from the AC source may be selected as desired. However, typically the signal will be of a relatively low frequency, for example, below 100 Hz, and may be selected based upon a particular implementation or the geographical region of use.

The microprocessor 160 can also use the data collected from the AC signal test to determine what the current leakage would be at high voltages. For example, if the AC signal is a 1 volt signal, it can readily be determined how much current would leak if the applied voltage was 1000 volts or higher. This allows a HIPOT test to be simulated without actually applying a high voltage.

The connection provided by elements 154/121 can also be in the form of a probe. In this configuration, the probe 154/121 can be applied to various locations and test points within the vehicle. For example, any point along the battery string of pack 104 can be probed. Similarly, other locations or test points in the vehicle 102 can be tested, such as at contactors 130,131, motors 106, an AC to DC or DC to AC converter within the vehicle, etc.

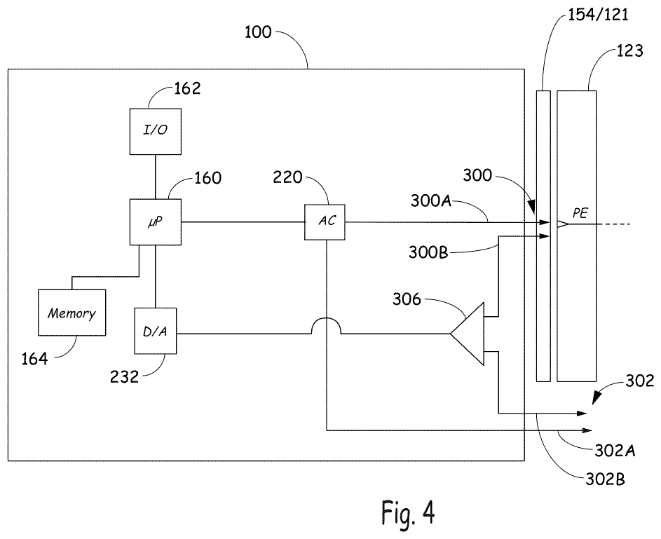

FIG. 4 shows another mode of operation of the maintenance device 100 for use in identifying faulty ground connections in vehicle 102. In this configuration, Kelvin connections 300 and 302 are used for determining conductance between ground points which should be electrically connected together. Kelvin connection 300 includes a driven connection 300A and sense connection 300B. Similarly, Kelvin connection 302 includes a driven connection 302A and a sense connection 302B. Kelvin connection 300 connects to the PE connection of charging port 123 through charging port 154/121. Kelvin connection 302 is configured as a test probe which can be electrically connected to various ground points by an operator. AC signal source 220 provides an AC forcing function which is applied to driven connection 300A for connection to a test point as well as the driven connection 302A for connection to a ground point, such as PE of plug 123. Any voltage differential between the two Kelvin connections 300, 302 is sensed using sense connections 300B, 302B by differential amplifier 306. This differential output from amplifier 306 is connected to digital to analog converter 232 and provided to the microprocessor 160 for evaluation.

In this configuration, an operator uses test probe 302 to connect to various ground points within the vehicle 192, including the vehicle chassis, the electrical ground of the battery, the electrical ground of motors or contactors, etc. The connections 302A,B of probe 302 can be push pin connectors or the like. The Kelvin connections allow even a small resistance between the two contact points to be measured. If the measured resistance is greater than a maximum resistance threshold, the microprocessor 160 can provide an indication through input/output circuitry of a potential safety problem to an operator and that a component of the vehicle 102 is not properly grounded.

In one configuration, charging plug 154/121 includes a plurality of exposed connectors such that an operator can connect to any potential charging port configuration or other electrical connector using jumper wires. These connections can be used to connect directly to a string of batteries within the batter pack 104, to other locations within the electrical power train including the contactors 130, 131, as well as other connections that provide data such as a proximity pilot connection or a control pilot connection. This also allows vehicles to be test which have non-standard charging ports 123. The insulation test and ground fault test discussed in connection with FIGS. 3 and 4 can be used in combination with data collected using the data connection 135/133 shown in FIG. 1. For example, data can be read back using an OBDII connection which identifies a fault in a battery, electrical component, electrical ground, or other device within the vehicle. Based upon this determination, microprocessor 160 can instruct an operator to perform a specific test on a specific component or test point of the vehicle using the AC forcing function provided by AC signal source 220. This can identify insulation breakdown or degradation, electrolyte seepage, burst cells within battery pack 104, other mechanical breakdown of internal components, contamination within the battery pack 104, seal failure, water ingress into components of vehicle 102, structural damage to the battery pack 104, or other potential safety related issues.

Although the present invention has been described with reference to preferred embodiments, workers skilled in the art will recognize that changes may be made in form and detail without departing from the spirit and scope of the invention. Although specific embodiments describe increasing the load or current, it should be understood that the change in applied load or current drawn can be either increasing or decreasing.

What is claimed is:

1. An apparatus for safety testing of electrical components in an electric vehicle, comprising:
a low voltage data connector configured to couple to a data port of the electric vehicle;
a test connector configured to couple a test signal to an electrical component of the electric vehicle;
a test signal source having a signal generator coupled to a voltage divider, wherein the voltage divider generates the test signal and a monitor signal;
measurement circuitry coupled to the monitor signal; and
a controller coupled to the low voltage data connector and the measurement circuitry configured identify a current leakage based upon the monitor signal.

2. The apparatus of claim 1 wherein the test signal comprises an AC forcing function.

3. The apparatus of claim 1 wherein the measurement circuitry comprises a differential amplifier which measures a difference between the test signal and the monitor signal.

4. The apparatus of claim 1 wherein the voltage divider comprises a resistor and a capacitor.

5. The apparatus of claim 1 wherein the test connector comprising a charging plug configured to couple to a charging port of the vehicle.

6. The apparatus of claim 1 wherein the test connector includes a plurality of connectors each configured to couple to an electrical connector of the vehicle.

7. The apparatus of claim 6 including a switch configured to selectively couple the monitor signal to at least one of the plurality of connectors.

8. The apparatus of claim 1 wherein the test connector includes a connection to an electrical ground of the vehicle.

9. The apparatus of claim 8 wherein the electrical ground comprises a PE connection.

10. The apparatus of claim 1 including a digital to analog converter which couples the monitor signal to the controller.

11. The apparatus of claim 1 wherein the controller is further configured to cause contactors of the vehicle to close.

12. The apparatus of claim 11 including a connection to a databus of the vehicle and wherein the controller communicates through the databus.

13. The apparatus of claim 1 including a connection to a databus of the vehicle and wherein the controller communicates through the databus.

14. The apparatus of claim 13 wherein the controller is configured to receive diagnostic information from the data connection to the vehicle.

15. The apparatus of claim 14 wherein the controller is configured to instruct an operator to perform a current leakage test on the vehicle based upon the diagnostic information.

16. The apparatus of claim 1 wherein the test connector provides a Kelvin connection.

17. The apparatus of claim 16 wherein a resistance between electrical ground and the Kelvin connection is measured.

18. The apparatus of claim 17 wherein the Kelvin connection is configured as a probe.

19. The apparatus of claim 18 wherein the controller instructs an operator where to place a probe.

20. The apparatus of claim 16 wherein the Kelvin connection is configured to couple to a PE connection of the vehicle.

21. The apparatus of claim 16 wherein the Kelvin connection receives an AC forcing function.

22. The apparatus of claim 16 including a differential amplifier configured to sense a voltage difference between sense connections of the Kelvin.

23. The apparatus of claim 12 wherein a battery voltage of the battery pack is retrieved through the databus.

24. The apparatus of claim 12 wherein a diagnostic information is retrieved through the databus.

25. The apparatus of claim 12 wherein current leakage fault information is retrieved through the databus.
